(19) United States
(12) Patent Application Publication
(10) Pub. No.: US 2026/0159941 A1
(43) Pub. Date: Jun. 11, 2026

(54) THIN FILM DEPOSITION APPARATUS, HOLDING TRAY AND THIN FILM DEPOSITION METHOD

(71) Applicant: INDUSTRIAL TECHNOLOGY RESEARCH INSTITUTE, Hsinchu (TW)

(72) Inventors: Shih-Hsiang LAI, New Taipei City (TW); Fu-Ching TUNG, Hsinchu City (TW); Hsuan-Fu WANG, Hsinchu City (TW); Yi-Jiun LIN, Hsinchu County (TW); Chih-Hung LIU, Hsinchu City (TW)

(73) Assignee: INDUSTRIAL TECHNOLOGY RESEARCH INSTITUTE, Hsinchu (TW)

(21) Appl. No.: 18/972,508

(22) Filed: Dec. 6, 2024

(51) Int. Cl. C23C 14/50; C23C 14/28; C23C 14/54

(52) U.S. Cl. CPC C23C 14/505; C23C 14/28; C23C 14/541

(57) ABSTRACT

Thin film deposition apparatus and method, and holding tray. Thin film deposition apparatus performs thin film deposition on substrate by targets, and includes chamber, holding tray, containers, substrate holder and local shutter disk. Chamber has vacuum space. Holding tray is rotatably disposed in vacuum space. Containers are disposed on holding tray, and target material to be deposited on substrate is placed in containers. Containers are located at different distances from geometric center of holding tray. Substrate holder carries substrate and is rotatably arranged in vacuum chamber. Containers are located between holding tray and substrate holder. Substrate holder and holding tray are not concentric. Local shutter disk is disposed in vacuum space, and located between substrate holder and containers. Local shutter disk has top surface, bottom surface and slot hole. Local shutter disk is placed close to bottom of substrate holder to confine deposition of plasma plumes on substrate.

### TECHNICAL FIELD

The disclosure relates to a thin film deposition apparatus, a holding tray and a thin film deposition method.

### BACKGROUND

With the development of the semiconductor technology, the demand for depositing GaN thin film on a substrate is continuously increased. Recently, the pulsed laser deposition (PLD) technique is used to overcome the limitation causing by conventional annealing of high temperature.

### SUMMARY

One embodiment of the disclosure provides a thin film deposition apparatus configured to perform thin film deposition on a substrate by a plurality of targets and including a chamber, a holding tray, a plurality of containers, a substrate holder and a local shutter disk. The chamber has a vacuum space. The holding tray is rotatably disposed in the vacuum space. The plurality of containers are disposed on the holding tray. The plurality of containers are located at different distances from a geometric center of the holding tray, and are located at uniform angular distances from the geometric center circumferentially. The plurality of containers are configured to accommodate the plurality of targets, respectively. The substrate holder is rotatably disposed in the vacuum space. The plurality of containers are located between the holding tray and the substrate holder. The substrate holder and the holding tray are disposed in an eccentric manner. A side of the substrate holder facing the plurality of containers is configured for the substrate to be disposed thereon. The local shutter disk is disposed in the vacuum space. The local shutter disk is located between the substrate holder and the plurality of containers and has a top surface, a bottom surface and at least one slot hole. The top surface and the bottom surface face away from each other. The top surface and the bottom surface face the substrate holder and the plurality of containers, respectively. The at least one slot hole penetrates through the top surface and the bottom surface. The substrate holder is located closer to the local shutter disk than the plurality of containers.

Another embodiment of the disclosure provides a holding tray configured to support a plurality of containers. The plurality of containers are configured to accommodate a plurality of targets, respectively. The holding tray has a plurality of first fixing structures. The plurality of first fixing structures are located at different distance from a geometric center of the holding tray and are located at uniform angular distances from the geometric center circumferentially. The plurality of first fixing structures are configured to be fixed to a plurality of second fixing structures of the plurality of containers, respectively.

Still another embodiment of the disclosure provides a thin film deposition method including: providing a thin film deposition apparatus; rotating the substrate holder to rotate the substrate on the substrate holder; rotating the holding tray to move one of the plurality of containers on the holding tray to a position closest to a geometric center of the substrate; stopping the holding tray from being rotated, and activating the target in the one of the plurality of the containers by an activating energy source to perform thin film deposition on the substrate via the at least one slot hole of the local shutter disk; then stopping the activating energy source from activating the target in the one of the plurality of the containers, and rotating the holding tray to move another one of the plurality of containers on the holding tray to a position closest to the geometric center of the substrate; and stopping the holding tray from being rotated, and activating the target in the another one of the plurality of the containers by the activating energy source to perform thin film deposition on the substrate via the at least one slot hole of the local shutter disk.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a thin film deposition apparatus according to a first embodiment of the disclosure and an activating energy source;

FIG. 2 is a perspective exploded view of a holding tray and containers of the thin film deposition apparatus in FIG. 1;

FIG. 3 is a top view of a substrate and the holding tray and the containers of the thin film deposition apparatus in FIG. 1;

FIGS. 4 to 8 are schematic views showing a thin film deposition method performed by the thin film deposition apparatus in FIG. 1;

FIG. 9 is a perspective exploded view of a holding tray and containers according to a second embodiment of the disclosure; and

FIG. 10 is a perspective view of a holding tray and containers according to a third embodiment of the disclosure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

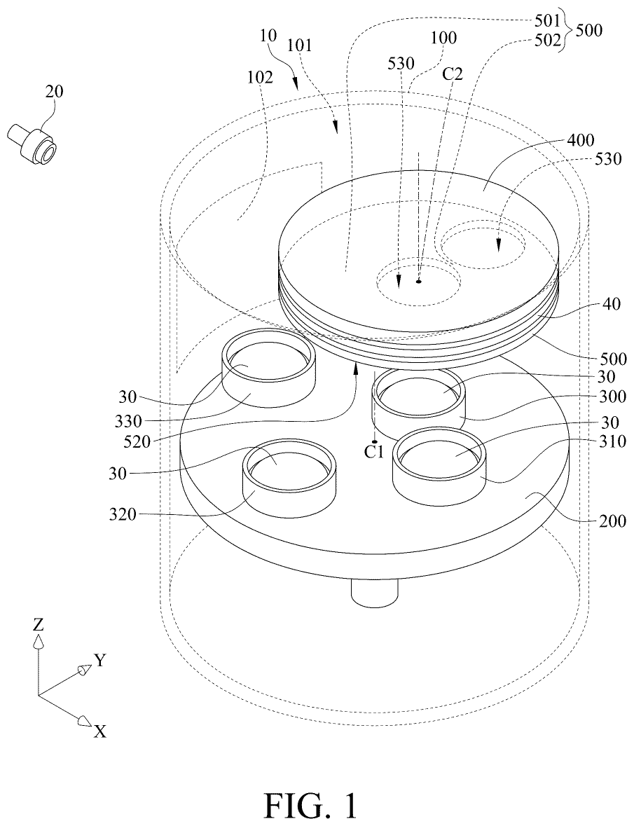

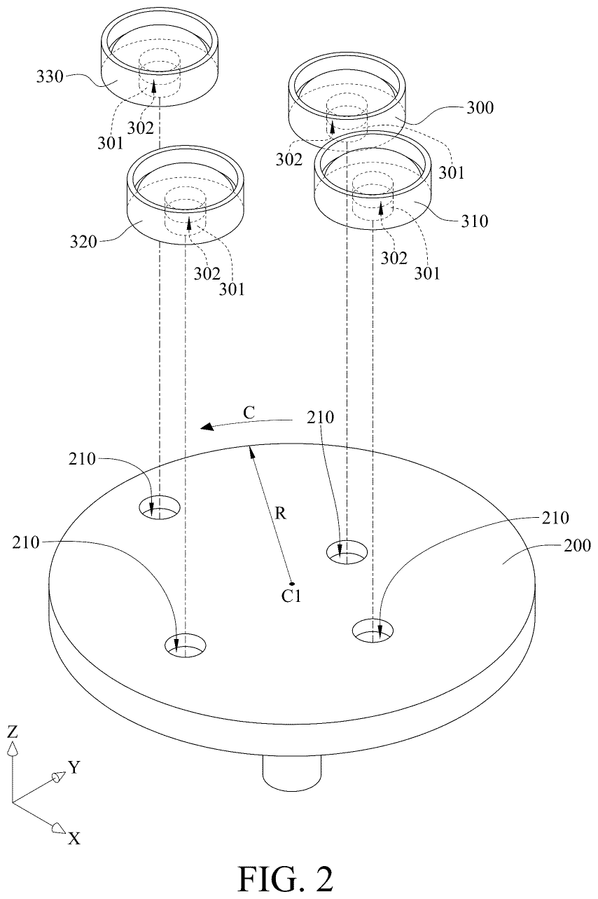

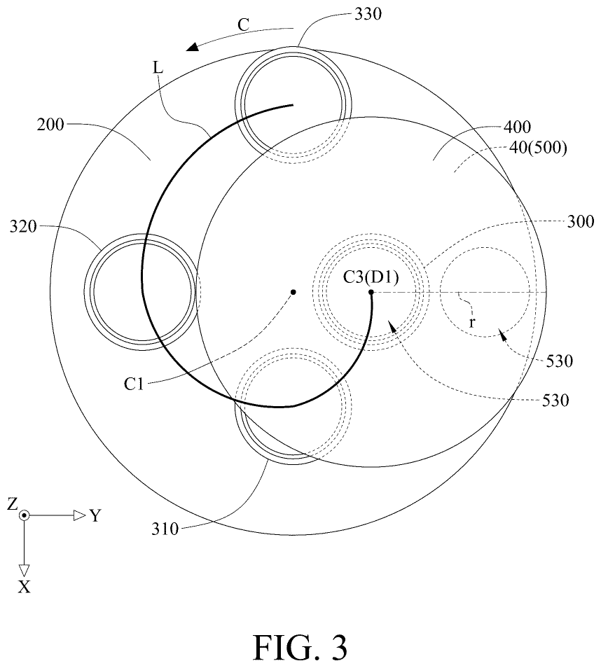

Please refer to FIGS. 1 to 3. FIG. 1 is a perspective view of a thin film deposition apparatus 10 according to a first embodiment of the disclosure and an activating energy source 20. FIG. 2 is a perspective exploded view of a holding tray 200 and containers 300, 310, 320 and 330 of the thin film deposition apparatus 10 in FIG. 1. FIG. 3 is a top view of a substrate 40 and the holding tray 200 and the containers 300, 310, 320 and 330 of the thin film deposition apparatus 10 in FIG. 1.

In this embodiment, the thin film deposition apparatus 10 is configured to be cooperated with the activating energy source 20 to perform thin film deposition on the substrate 40 via a plurality of targets 30. The thin film deposition apparatus 10 includes, for example, a chamber 100, the holding tray 200, the containers 300, 310, 320 and 330, a substrate holder 400 and a local shutter disk 500. The activating energy source 20 is configured to emit a laser beam. In some embodiments, one or more optical assemblies (not shown) may be disposed between the activating energy source 20 and the containers 300, 310, 320 and 330 to adjust the optical path of the laser beam emitted from the activating energy source 20. The size of the substrate 40 is, for example, 6 inches. Note that the thin film deposition apparatus 10 may perform thin film deposition on substrates 40 of various sizes, such as 4 inches, 8 inches, 12 inches or the like.

In this embodiment, the chamber 100 has, for example, a vacuum space 101 and a transparent window 102. In this embodiment, the chamber 100 in in a cylindrical shape, but the disclosure is not limited thereto. In other embodiments, if the substrate has a small size, the chamber may be in a spherical shape; if the substrate has a large size, the chamber may be in a cubic shape.

The transparent window 102 is configured for the laser beam emitted from the activating energy source 20 to enter into the vacuum space 101. Note that the activating energy source 20 cooperating with the thin film deposition apparatus 10 of this embodiment is not limited to being configured to emit laser beam. In other embodiments, the activating energy source cooperating with the thin film deposition apparatus may be configured to emit energy electron beam or plasma. In such embodiments, the activating energy source may be included in the thin film deposition apparatus and may be located in the vacuum space of the chamber.

The holding tray 200 is rotatably disposed in the vacuum space 101. For example, the holding tray 200 is rotatably disposed in the chamber 100. In addition, in this embodiment, the holding tray 200 has a plurality of first fixing structures 210. The first fixing structures 210 are, for example, mounting holes, and are located at different distances from a geometric center C1 of the holding tray 200. Moreover, in this embodiment, the first fixing structures 210 are spaced apart from one another by uniform distances along a radial direction R of the holding tray 200, and are spaced apart from one another by uniform distances along a circumferential direction C. That is, the first fixing structures 210 are located at uniform angular distances on the holding tray 200 circumferentially.

The containers 300, 310, 320 and 330 are, for example, crucibles and are configured to accommodate the targets 30, respectively. The containers 300, 310, 320 and 330 are disposed on the holding tray 200. In detail, the containers 300, 310, 320 and 330 each have a second fixing structure 301. The second fixing structures 301 are, for example, pins, and are disposed in a mounting recess 302 of each of the containers 300, 310, 320 and 330. The second fixing structures 301 of the containers 300, 310, 320 and 330 are fixed in the first fixing structures 210, respectively. Thus, in this embodiment, the containers 300, 310, 320 and 330 are located at different distance from the geometric center C1 of the holding tray 200. The containers 300, 310, 320 and 330 are spaced apart from one another by uniform distances along the radial direction R of the holding tray 200, and are spaced apart from one another by uniform distances along the circumferential direction C. That is, the containers 300, 310, 320 and 330 are located at uniform angular distances on the holding tray 200 circumferentially. For example, as shown in FIGS. 2 and 3, the first fixing structures 210 or the containers 300, 310, 320 and 330 may be understood as being arranged along a spiral line L in FIG. 3 (as shown in FIG. 3), and the angle between adjacent two of the containers 300, 310, 320 and 330 is about 90 degrees.

The substrate holder 400 is rotatably disposed in the vacuum space 101. The substrate holder 400 is rotatably disposed in, for example, the chamber 100. In addition, in one embodiment, the substrate holder 400 may include a heater. The containers 300, 310, 320 and 330 are located between the holding tray 200 and the substrate holder 400. The substrate holder 400 and the holding tray 200 are disposed in an eccentric manner. That is, there is an eccentric distance between the geometric center C1 of the holding tray 200 and the geometric center C3 of the substrate 40. A side of the substrate holder 400 facing the containers 300, 310, 320 and 330 supports the substrate 40. In this embodiment, the substrate holder 400 includes a heater configured to heat the substrate 40, but the disclosure is not limited thereto. In other embodiments, the substrate holder may not include the heater, and a heater external to the thin film deposition apparatus may be used to heat the substrate.

The local shutter disk 500 is disposed in the vacuum space 101, and is made of, for example, stainless steel. For example, the local shutter disk 500 is movably disposed or fixed in the vacuum space 101, such as being movably disposed or fixed on the chamber 100. In addition, the local shutter disk 500 is located between the substrate holder 400 and the containers 300, 310, 320 and 330, and has, for example, a top surface 510, a bottom surface 520 and at least one slot hole 530. The top surface 510 and the bottom surface 520 face away from each other. The top surface 510 and the bottom surface 520 face the substrate holder 400 and the containers 300, 310, 320 and 330, respectively. The slot holes 530 penetrate through the top surface 510 and the bottom surface 520. The local shutter disk 500 is disposed close to a position under the substrate holder 400 to confine deposition of plasma plumes on the substrate.

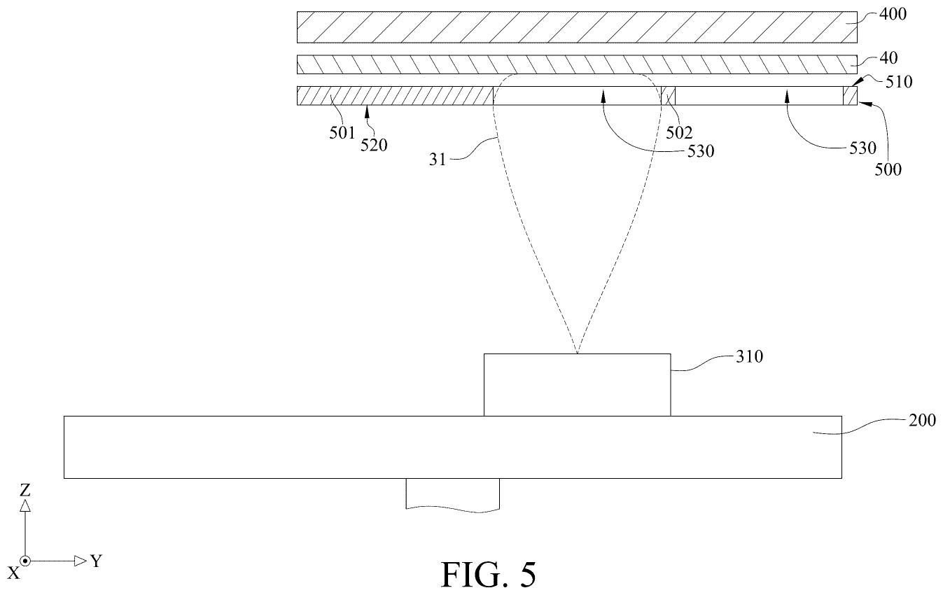

Additionally, in this embodiment, the local shutter disk 500 includes a shutter part 501 and a hole arranging part 502 connected to each other, as shown in FIG. 5. The shutter part 501 and the hole arranging part 502 together form the top surface 510 and the bottom surface 520. The slot holes 530 are located on the hole arranging part 502. The shutter part 501 covers a part of the substrate 40. Also, in this embodiment, the local shutter disk 500 and the substrate holder 400 are in a shape of circular disk. The size of the local shutter disk 500 may be larger than or equal to the size of the substrate 40, and may be smaller than twice of the size of the substrate 40. In addition, the local shutter disk 500 is not limited to being in a shape of circular disk. In other embodiments, although not shown, the local shutter disk may be in a shape of square or rectangular disk.

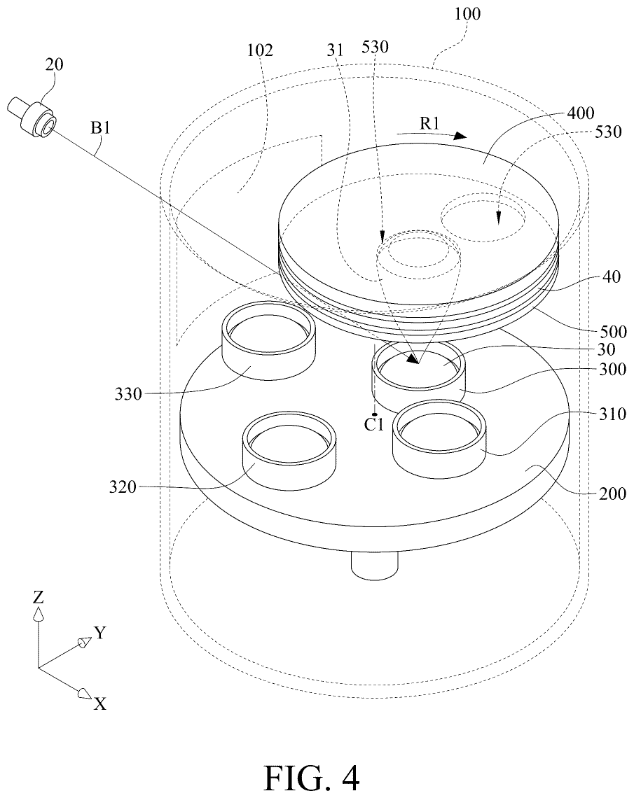

Please refer to FIGS. 1 to 8, where FIGS. 4 to 8 are schematic views showing a thin film deposition method performed by the thin film deposition apparatus 10 in FIG. 1.

First, as shown in FIG. 1, the thin film deposition apparatus 10 is provided. For example, four containers 300, 310, 320 and 330 are disposed on the holding tray 200 around the geometric center C1, and are located at uniform angular distances (about 90 degrees) on the holding tray 200 circumferentially. Then, as shown in FIGS. 1 to 4, the substrate holder 400 is rotated along a rotating direction R1 to force the substrate 40 on the substrate holder 400 to be continuously rotated along the rotating direction R1. Then, as shown in FIGS. 1 and 3, the holding tray 200 is rotated about the geometric center C1, and is rotated along the circumferential direction C to move the container 300 on the holding tray 200 to a position D1 (right under the geometric center C3) closest to the geometric center C3 of the substrate 40.

Then, as shown in FIGS. 4 and 5, the holding tray 200 is stopped from being rotated, and the laser beam B1 emitted from the activating energy source 20 passes through the transparent window 102 to activate the target 30 in the container 300, thereby allowing the plasma plume 31 generated by activation to perform thin film deposition on the substrate 40 via the slot hole 530 of the local shutter disk 500. For example, the activating energy source 20 activates the target 30 and thus the plasma plume 31 is generated. The plasma plume 31 passes through the slot hole 530 to perform thin film deposition on the substrate 40 in a concentrative manner.

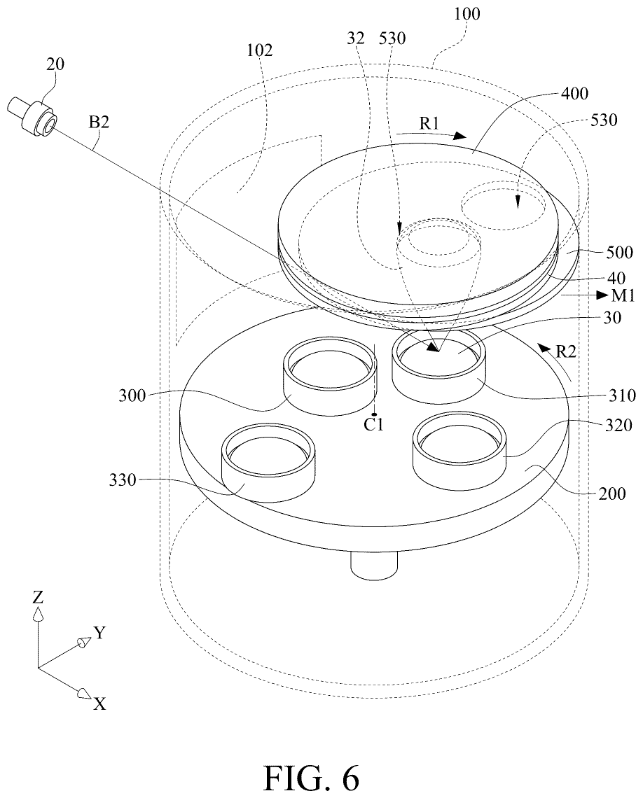

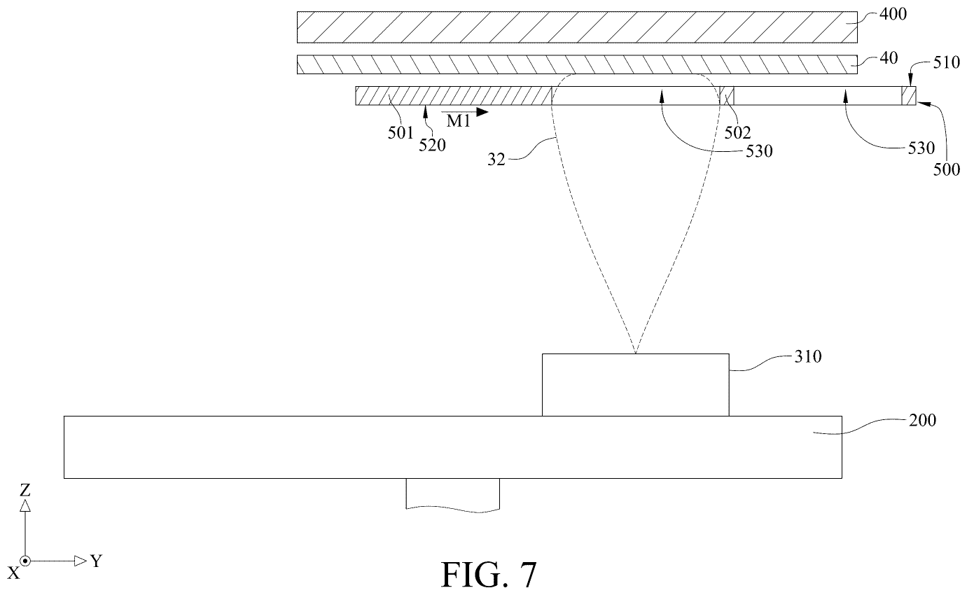

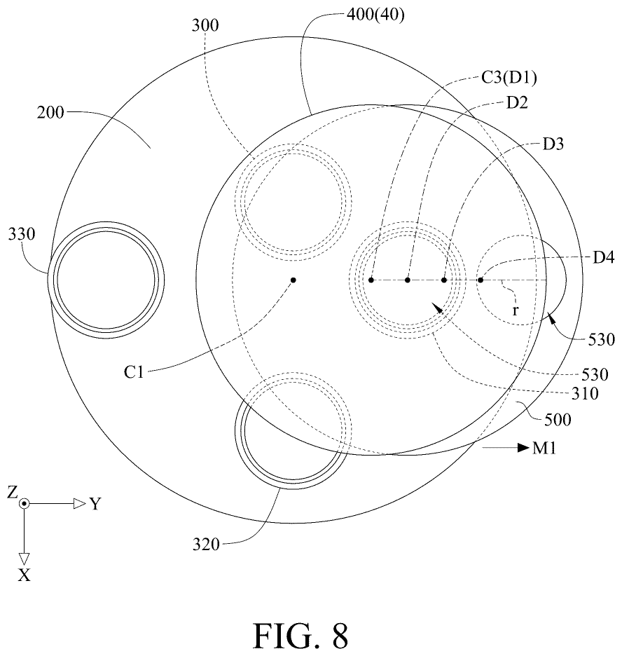

Then, as shown in FIGS. 6 to 8, the activating energy source 20 is stopped from activating the target 30 in the container 300, and the holding tray 200 is rotated again along the rotating direction R2 (the same as the circumferential direction C) to move another container 310 on the holding tray 200 to a position D2 closest to the geometric center C3 of the substrate 40 (rotated by about 90 degrees to be located near the aforementioned position D1) (as shown in FIG. 8). Then, as shown in FIGS. 6 and 7, the holding tray 200 is stopped from being rotated, and a laser beam B2 emitted from the activating energy source 20 passes through the transparent window 102 to activate the target 30 in another container 310, thereby allowing the plasma plume 32 generated by the activation to perform thin film deposition on the substrate 40 via the slot hole 530 of the local shutter disk 500. Further, in this embodiment, in the steps shown in FIGS. 6 and 7, for example, the activating energy source 20 may be moved according to the position of the container 310 to allow the activating energy source 20 to activate the target 30 in the container 310. As long as the target 30 in the container 310 is allowed to be activated at a desired angle, the movement of the activating energy source 20 may be realized by translation or rotation. Moreover, in this embodiment, in the steps shown in FIGS. 6 and 7, for example, the local shutter disk 500 may be fixed or moved along a moving direction M1 according to the position of the container 310. Note that in the steps shown in FIGS. 6 and 7, the substrate holder 400 and the substrate 40 are still continuously rotated along the rotating direction R1.

Note that the detail processes for sequentially activating the targets 30 in the containers 300 and 310 are exemplarily described above, and the targets 30 in other two containers 320 and 330 are activated in a similar manner, and thus the repeated descriptions are omitted. Also, in this step, the substrate holder 400 and the substrate 40 are still continuously rotated along the rotating direction R1.

As shown in FIGS. 2, 3 and 8, the containers 300, 310, 320 and 330 or the first fixing structures 210 of the holding tray 200 are located at different distances from the geometric center C1 of the holding tray 200. Thus, when the containers 300, 310, 320 and 330 are moved to central positions D1, D2, D3 and D4 located closest to the geometric center C3 of the substrate 40, they roughly are arranged in a straight line and located right under a right radial reference line r of the substrate 40 (the right radial reference line r shown in FIG. 3). As such, the plasma plumes generated by activating the four targets by laser beam confine the concentration of atomic groups to be uniform via the slot hole 530 of the local shutter disk 500, thereby performing exclusive thin film depositions on different areas of the substrate 40, respectively. Therefore, thin film is allowed to be uniformly deposited on the substrate 40 having a large size. Also, the substrate 40 is continuously rotated along the rotating direction R1 to perform uniform thin film deposition on the whole surface of the substrate.

In addition, as shown in FIGS. 4 and 6, in this embodiment, the activating energy source 20 is firstly stopped from activating the target 30 in the container 300, and then the holding tray 200 is rotated. Thus, the plasma plumes 31 and 32 generated by the targets 30 in different containers 300 and 310 are prevented from disturbing each other. Also, during rotation, the plasma plume 31 has enough time to be absorbed on a surface of the wafer (i.e., substrate 40) to migrate, arrange, and perform film growth without being disturbed by colliding with or being blocked by the plasma plume 32. Accordingly, the impurity and defect in the thin film deposited on the substrate 40 are allowed to be reduced, thereby improving the uniformity thereof.

Further, as shown in FIGS. 1, 5 and 7, since the plasma plumes (e.g., plasma plumes 31 and 32 and the plasma plumes generated by activating the targets 30 in the containers 320 and 330) generated by activating the targets 30 in the containers 300, 310, 320 and 330 perform thin film deposition on the substrate 40 in a concentrative manner via the slot hole 530 of the local shutter disk 500, the slot hole 530 of the local shutter disk 500 allows the containers 300, 310, 320 and 330 to perform exclusive thin film depositions on different areas of the substrate 40 in a concentrative manner, respectively. Moreover, a part of each plasma plume generated by activating the targets 30 in the containers 300, 310, 320 and 330 that does not pass through the slot hole 530 is blocked by the shutter part 501, and thus is prevented from performing thin film deposition on the substrate 40, which further ensures the thin film deposition is performed in specific areas of the substrate in a concentrative manner.

Note that in other embodiments, the local shutter disk may be fixed in the vacuum space, such as being fixed to the vacuum chamber. In such embodiments, the number of the slot holes of the local shutter disk may be equal to or different from the number of the containers, and the targets in the containers may be configured to perform thin film deposition on the substrate via the slot holes, respectively.

Furthermore, in this embodiment, the local shutter disk 500 has multiple slot holes 530 to ensure almost all of the plasma plumes generated by activating the targets 30 in the containers 300, 310, 320 and 330 are allowed to perform thin film deposition on the substrate 40. However, the disclosure is not limited thereto. In other embodiments, the local shutter disk may have one slot hole.

Other embodiments are described below for illustrative purposes. It is to be noted that the following embodiments use the reference numerals and a part of the contents of the above embodiments, the same reference numerals are used to denote the same or similar elements, and the description of the same technical contents is omitted. For the description of the omitted part, reference may be made to the above embodiments, and details are not described in the following embodiments.

In the first embodiment, there are four first fixing structures and four containers around the geometric center C1 and located at uniform angular distances (about 90 degrees) from the geometric center C1 circumferentially. However, the disclosure is not limited by the number of the first fixing structures of the holding tray and the number of the containers. As long as the first fixing structures or the containers are located at different distances from the geometric center of the holding tray and are located at uniform angular distances from the geometric center C1 circumferentially, the number of the first fixing structures and the number of the containers may be adjusted according to the size of the substrate.

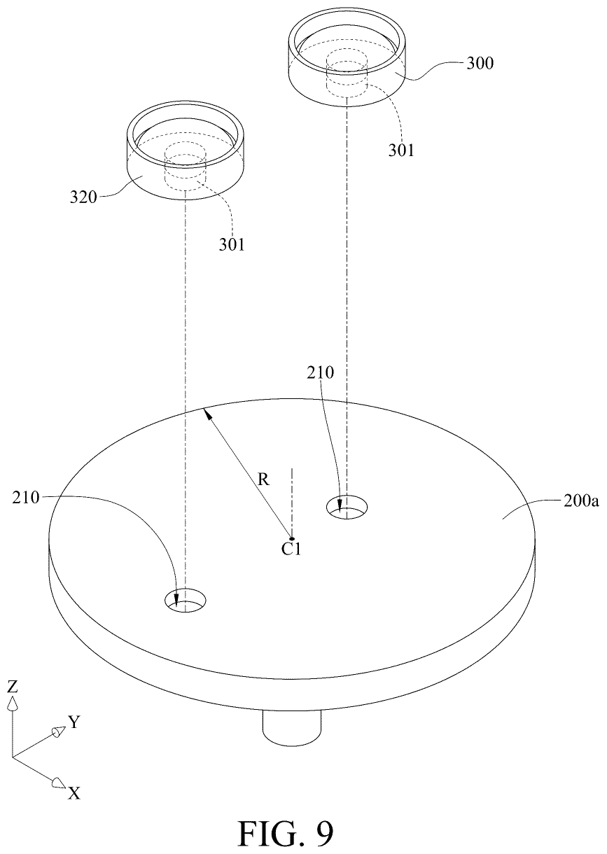

For example, please refer to FIG. 9 that is a perspective exploded view of a holding tray 200a and containers 300 and 320 according to a second embodiment of the disclosure. In this embodiment, the holding tray 200a has, for example, two first fixing structures 210. The two first fixing structures 210 fix the two containers 300 and 320 to the holding tray 200a via two second fixing structures 301, respectively. In one embodiment, the two first fixing structures 210 are spaced apart from each other along the radial direction R of the holding tray 200a by uniform distances, and are located at uniform angular distances from the geometric center C1 circumferentially. Note that the holding tray 200a and the two containers 300 and 320 in this embodiment may be applied to the thin film deposition apparatus 10 of the first embodiment.

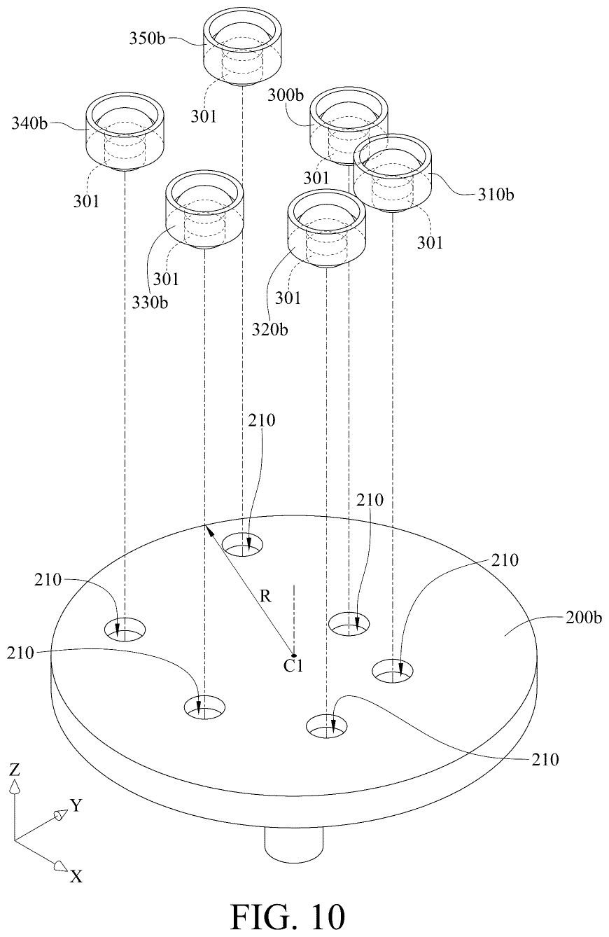

Alternatively, please refer to FIG. 10 that is a perspective view of a holding tray 200b and containers 300b, 310b, 320b, 330b, 340b and 350b according to a third embodiment of the disclosure. In this embodiment, the holding tray 200b has, for example, six first fixing structures 210. The six first fixing structures 210 fix the six containers 300b, 310b, 320b, 330b, 340b and 350b to the holding tray 200b via six second fixing structures 301, respectively. In one embodiment, the six first fixing structures 210 are spaced apart from each other along the radial direction R of the holding tray 200b by uniform distances, and are located at uniform angular distances from the geometric center C1 circumferentially. Note that the holding tray 200b and the six containers 300b, 310b, 320b, 330b, 340b and 350b in this embodiment may be applied to the thin film deposition apparatus 10 of the first embodiment.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A thin film deposition apparatus, configured to perform thin film deposition on a substrate by a plurality of targets and comprising:
a chamber, having a vacuum space;
a holding tray, rotatably disposed in the vacuum space;
a plurality of containers, disposed on the holding tray, wherein the plurality of containers are located at different distances from a geometric center of the holding tray, and are located at uniform angular distances from the geometric center circumferentially, and the plurality of containers are configured to accommodate the plurality of targets, respectively;
a substrate holder, rotatably disposed in the vacuum space, wherein the plurality of containers are located between the holding tray and the substrate holder, the substrate holder and the holding tray are disposed in an eccentric manner, and a side of the substrate holder facing the plurality of containers is configured for the substrate to be disposed thereon; and
a local shutter disk, disposed in the vacuum space, wherein the local shutter disk is located between the substrate holder and the plurality of containers and has a top surface, a bottom surface and at least one slot hole, the top surface and the bottom surface face away from each other, the top surface and the bottom surface face the substrate holder and the plurality of containers, respectively, the at least one slot hole penetrates through the top surface and the bottom surface, and the substrate holder is located closer to the local shutter disk than the plurality of containers.

2. The thin film deposition apparatus according to claim 1, wherein the local shutter disk is movably disposed in the vacuum space.

3. The thin film deposition apparatus according to claim 1, wherein the at least one slot hole of the local shutter disk comprises a plurality of slot holes, and the plurality of slot holes are located at different distance from a geometric center of the local shutter disk.

4. The thin film deposition apparatus according to claim 1, wherein the local shutter disk comprises a shutter part and a hole arranging part connected to each other, the shutter part and the hole arranging part together form the top surface and the bottom surface, the at least one slot hole is located on the hole arranging part, and the shutter part is configured to cover a part of the substrate on the substrate holder.

5. The thin film deposition apparatus according to claim 1, wherein a size of the local shutter disk is larger than or equal to a size of the substrate, and is smaller than twice of the size of the substrate.

6. The thin film deposition apparatus according to claim 1, wherein the holding tray has a plurality of first fixing structures, the plurality of containers each have a second fixing structure, the plurality of first fixing structures are located at different distances from the geometric center of the holding tray, and the plurality of first fixing structures are fixed to the second fixing structures, respectively.

7. The thin film deposition apparatus according to claim 6, wherein the plurality of first fixing structures are mounting holes, and the second fixing structures are mounting pins.

8. The thin film deposition apparatus according to claim 6, wherein the plurality of first fixing structures are spaced apart from each other by uniform distances along a radial direction and a circumferential direction of the holding tray.

9. The thin film deposition apparatus according to claim 1, wherein the substrate holder comprises a heater.

10. The thin film deposition apparatus according to claim 1, wherein the chamber has a transparent window configured to allow a laser beam emitted from an activating energy source to enter into the vacuum space.

11. A holding tray, configured to support a plurality of containers, wherein the plurality of containers are configured to accommodate a plurality of targets, respectively, the holding tray has a plurality of first fixing structures, the plurality of first fixing structures are located at different distance from a geometric center of the holding tray and are located at uniform angular distances from the geometric center circumferentially, and the plurality of first fixing structures are configured to be fixed to a plurality of second fixing structures of the plurality of containers, respectively.

12. The holding tray according to claim 11, wherein the plurality of first fixing structures are mounting holes, and the plurality of second fixing structures are mounting pins.

13. A thin film deposition method, comprising:
providing a thin film deposition apparatus comprising a chamber, a holding tray, a plurality of containers, a substrate holder and a local shutter disk, wherein the chamber has a vacuum space, the holding tray is rotatably disposed in the vacuum space, the plurality of containers are disposed on the holding tray, the plurality of containers are located at different distances from a geometric center of the holding tray, and are located at uniform angular distances from the geometric center circumferentially, the plurality of containers are configured to accommodate a plurality of targets, respectively, the substrate holder is rotatably disposed in the vacuum space, the plurality of containers are located between the holding tray and the substrate holder, the substrate holder and the holding tray are disposed in an eccentric manner, a side of the substrate holder facing the plurality of containers is configured for a substrate to be disposed thereon, the local shutter disk is disposed in the vacuum space, the local shutter disk is located between the substrate holder and the plurality of containers and has a top surface, a bottom surface and at least one slot hole, the top surface and the bottom surface face away from each other, the top surface and the bottom surface face the substrate holder and the plurality of containers, respectively, the at least one slot hole penetrates through the top surface and the bottom surface, and the substrate holder is located closer to the local shutter disk than the plurality of containers;
rotating the substrate holder to rotate the substrate on the substrate holder;
rotating the holding tray to move one of the plurality of containers on the holding tray to a position closest to the geometric center of the substrate; and
stopping the holding tray from being rotated, and activating the target in the one of the plurality of the containers by an activating energy source to perform thin film deposition on the substrate via the at least one slot hole of the local shutter disk.

14. The thin film deposition method according to claim 13, after stopping the holding tray from being rotated, and activating the target in the one of the plurality of the containers by the activating energy source to perform thin film deposition on the substrate via the at least one slot hole of the local shutter disk, the method further comprising:
stopping the activating energy source from activating the target in the one of the plurality of the containers, and rotating the holding tray to move another one of the plurality of containers on the holding tray to a position closest to the geometric center of the substrate; and
stopping the holding tray from being rotated, and activating the target in the another one of the plurality of the containers by the activating energy source to perform thin film deposition on the substrate via the at least one slot hole of the local shutter disk.

15. The thin film deposition method according to claim 14, wherein in stopping the holding tray from being rotated, and activating the target in the another one of the plurality of the containers by the activating energy source to perform thin film deposition on the substrate via the at least one slot hole of the local shutter disk, the activating energy source is moved according to the position of the another one of the plurality of the containers to activate the target in the another one of the plurality of the containers.

16. The thin film deposition method according to claim 14, wherein the local shutter disk is movably disposed in the vacuum space.

17. The thin film deposition method according to claim 16, wherein in stopping the holding tray from being rotated, and activating the target in the another one of the plurality of the containers by the activating energy source to perform thin film deposition on the substrate via the at least one slot hole of the local shutter disk, the local shutter disk is moved according to the position of the another one of the plurality of the containers to perform thin film deposition on the substrate via the at least one slot hole of the local shutter disk.

18. The thin film deposition method according to claim 13, wherein the chamber has a transparent window configured to allow a laser beam emitted from the activating energy source to enter into the vacuum space.

19. The thin film deposition method according to claim 13, wherein the at least one slot hole of the local shutter disk comprises a plurality of slot holes, and the plurality of slot holes are located at different distance from a geometric center of the local shutter disk.

20. The thin film deposition method according to claim 13, wherein the local shutter disk comprises a shutter part and a hole arranging part connected to each other, the shutter part and the hole arranging part together form the top surface and the bottom surface, the at least one slot hole is located on the hole arranging part, and the shutter part is configured to cover a part of the substrate on the substrate holder.
